(19) United States
(12) Patent Application Publication
(10) Pub. No.: US 2026/0066171 A1
(43) Pub. Date: Mar. 5, 2026

(54) Crystallized YPtBi (111) Topological Semi-Metal (TSM) Induced by (111) or (002)-(111) Buffers

(71) Applicant: Western Digital Technologies, Inc., San Jose, CA (US)

(72) Inventors: Quang LE, San Jose, CA (US); Brian R. YORK, San Jose, CA (US); Cherngye HWANG, San Jose, CA (US); Xiaoyong LIU, San Jose, CA (US); Hisashi TAKANO, Fujisawa-shi (JP)

(73) Assignee: Western Digital Technologies, Inc., San Jose, CA (US)

(21) Appl. No.: 19/313,349

(22) Filed: Aug. 28, 2025

Related U.S. Application Data
(60) Provisional application No. 63/689,048, filed on Aug. 30, 2024.

(51) Int. Cl. H01F 10/32; G01R 33/09; G11B 5/00; G11B 5/39; H10B 61/00; H10N 50/10; H10N 50/85

(52) U.S. Cl. CPC H01F 10/3268; G11B 5/39; H10B 61/20; H10N 50/10; H10N 50/85; G01R 33/098; G11B 2005/0021

(57) ABSTRACT

The present disclosure generally relates to spintronic devices comprising a YPtBi layer having a (111) orientation. The spintronic stack further comprises a ferromagnetic layer and a buffer layer. The buffer layer has a (002) or (111) orientation, which promotes the (111) orientation of the YPtBi layer. The buffer layer comprises an amorphous oxide or nitride layer, an amorphous metal layer disposed on the amorphous oxide or nitride layer, a textured pre-seed layer disposed on the amorphous metal layer, and one of: a (002) hexagon or (111) fcc layer, a B2 alloy layer, or first and second bcc or B2 alloy layers.

### CROSS-REFERENCE TO RELATED APPLICATIONS

This application claims benefit of U.S. provisional patent application Ser. No. 63/689,048, filed Aug. 30, 2024, which is herein incorporated by reference.

### BACKGROUND OF THE DISCLOSURE

### Field of the Disclosure

Embodiments of the present disclosure generally relate to spintronic devices with a textured buffer layer for growing a topological semi-metal (TSM) material.

### Description of the Related Art

Spintronic devices have been used in various sensor, data storage, memory, and logic applications, and have shown promise in recent years to support devices for artificial intelligence applications. Various materials have been attempted in the search for efficient spin Hall effect (SHE) materials for such devices, among which are various topological insulator materials with high spin Hall angles.

YPtBi layers are narrow band gap topological semi-metals having both giant spin Hall effect and good thermal robustness. YPtBi is a material that has been proposed in various spin-orbit torque (SOT) device applications, such as for a spin Hall layer for magnetoresistive random access memory (MRAM) devices, magnetic recording read heads, sensors, and energy-assisted magnetic recording (EAMR) magnetic recording heads. However, utilizing YPtBi materials in commercial SOT applications can present several obstacles. For example, YPtBi materials require specific buffer layers and/or interlayers, as well as optimal processing conditions, to achieve the desired orientation.

Therefore, there is a need for an improved SOT device utilizing TSM layer(s) having a desired (111) crystal orientation.

### SUMMARY OF THE DISCLOSURE

The present disclosure generally relates to spintronic devices comprising a YPtBi layer having a (111) orientation. The spintronic stack further comprises a ferromagnetic layer and a buffer layer. The buffer layer has a (002) or (111) orientation, which promotes the (111) orientation of the YPtBi layer. The buffer layer comprises an amorphous oxide or nitride layer, an amorphous metal layer disposed on the amorphous oxide or nitride layer, a textured pre-seed layer disposed on the amorphous metal layer, and one of: a (002) hexagonal or (111) fcc layer, a B2 alloy layer, or first and second bcc or B2 alloy layers.

In one embodiment, a spintronic stack comprises a YPtBi layer having a (111) orientation, a ferromagnetic layer, and a buffer layer, the buffer layer comprising: an amorphous oxide or nitride layer, an amorphous metal layer disposed on the amorphous oxide or nitride layer, a textured pre-seed layer disposed on the amorphous metal layer, and a (002) hexagonal or (111) fcc layer disposed on the textured pre-seed layer, the (002) hexagonal or (111) fcc layer having a-axis lattice parameters around 4.6 Å to 4.8 Å when the (002) hexagonal or (111) fcc layer has a (002) hexagonal orientation, the (002) hexagonal or (111) fcc layer having a (002) hexagonal orientation comprising an alloy material selected from the group consisting of: Fe₂X, where X is one of Ti, Mo, Ta, or Ta_{z}W_{1-z}, (where z is a numeral between 0.005 and 1), Co₂X alloys, where X is one of Ti, Nb, Ta, TaAl, or NbAl, and (CoFe)₂Ta. A number of the Co₂X alloys exist both as hexagonal and fcc phases. The (111) fcc materials of the (002) hexagonal or (111) fcc layer have a-axis lattice parameters in the range of about 6.6 Å to about 6.8 Å where (cF24—space group Fd-3m) materials are selected from the group consisting of: Co₂X, where X is one of Ti, Nb, Ta, Hf, or Zr, (cF24—space group F-43m materials), Ni₅Hf, and X₅Zr alloys, where X is one of Co, Ni, NiFe, or CuNi. There are also fcc (111) ternary alloys (cF12—space group F-43m) having a-axis lattice parameters in the range of about 6.4 Å to 6.7 Å that can used as buffer layers, such as AuScSn, BiCoZr, BiNiY, or Bi—XQ alloys, where X is one of Ni, Pt, or Pd, and Q is a rare earth, such as Gd and Dy.

In another embodiment, a spintronic stack comprises a YPtBi layer having a (111) orientation, a ferromagnetic layer, and a buffer layer, the buffer layer comprising: an amorphous oxide or nitride layer, an amorphous metal layer disposed on the amorphous oxide or nitride layer, a textured pre-seed layer disposed on the amorphous metal layer, and a B2 or bcc alloy layer disposed on the textured pre-seed layer, the B2 or bcc alloy layer with a-axis lattice parameter of about 3.1 Å to about 3.4 Å comprising a material selected from the group consisting of: MgAu, Sc—X, where X is one of Al, Ni, Pd, or Au, Ti—X, where X is one of Ru, Rh, Pd, Pt, or Au, Ru—X, where X is one of Ti, Zr, hf, or Ta, (where Ti—X and Ru—X need not be stoichiometric), TaₓW₁₋ₓ (where x is a numeral between 0.005 and 1), Ir—X, where X is one of Sc, Ti, Y, or Zr, Hf—X, where X is one of Ti, Co(Fe, Ni, Nb)Zr, Ni, Ru, Pt, Zr—X, where X is one of Ti, Co, Cu, Rh, Ru, and Os, and B2-alloy ternaries including (AlMo)_{0.5}Ti, (AlV)_{0.5}Ru, (AlZr)_{0.5}Ru, (HfTi)_{0.5}Ru, or Co(Fe, Ni, Nb)Zr, where some example include: (Co4Ni)_{0.2}Zr, (Co4Fe)_{0.2}Zr, and (NbZr3)_{0.25}Co.

In yet another embodiment, a spintronic stack comprises a YPtBi layer having a (111) orientation, a ferromagnetic layer, and a buffer layer, the buffer layer comprising: an amorphous oxide or nitride layer, an amorphous metal layer disposed on the amorphous oxide or nitride layer, a textured pre-seed layer disposed on the amorphous metal layer, a first bcc or B2 alloy with slightly lower a-axis lattice parameter layer disposed on the textured pre-seed layer, the first bcc or B2 alloy layer comprising a material selected from the group consisting of: RuTi, RhTi, (HfTi)_{0.5}Ru, or Co(Fe, Ni, Nb)Zr, where examples include (Co4Ni)_{0.2}Zr, and (Co4Fe)_{0.2}Zr, and a second bcc or B2 layer with a slightly higher a-axis lattice parameter disposed on the first bcc or B2 layer, the second bcc or B2 layer comprising a material selected from the group consisting of: Zr—X, where X is one of Ti, Co, Cu, Ru, Rh, or Os, Ir—X, where X is one of Sc, Y, or Zr, and TaₓW₁₋ₓ (where x is a numeral between 0.005 and 1).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a magnetic recording head with a spintronic device.

FIG. 2 is a fragmented, cross-sectional view of certain embodiments of a read/write head with a spintronic device.

FIG. 3A is a schematic illustration of a forward spintronic material stack, according one embodiment.

FIG. 3B is a schematic illustration of a reverse spintronic material stack, according another embodiment.

FIGS. 4A-4D illustrate various buffer layers for use in the spintronic stacks of FIGS. 3A-3B, according to various embodiments.

FIG. 5A is a schematic cross-sectional view of a SOT device for use in a MAMR magnetic recording head, such as the MAMR magnetic recording head of the drive of FIG. 1 or other suitable magnetic media drives.

FIGS. 5B-5C are schematic MFS views of certain embodiments of a portion of a MAMR magnetic recording head with a SOT device of FIG. 5A.

FIG. 6 is a schematic cross-sectional view of a SOT MTJ used as a MRAM device.

FIG. 7 illustrates a schematic of a simplified deep neural network (DNN) or logic device, according to one embodiment.

FIG. 8 illustrates a spin orbital-spin orbital (SO-SO) device, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to spintronic devices comprising a YPtBi layer having a (111) orientation. The spintronic stack further comprises a ferromagnetic layer and a buffer layer. The buffer layer has a (002) or (111) orientation, which promotes the (111) orientation of the YPtBi layer. The buffer layer comprises an amorphous oxide or nitride layer, an amorphous metal layer disposed on the amorphous oxide or nitride layer, a textured pre-seed layer disposed on the amorphous metal layer, and one of: a (002) hexagon or (111) fcc layer, a B2 alloy layer, or first and second bcc or B2 alloy layers.

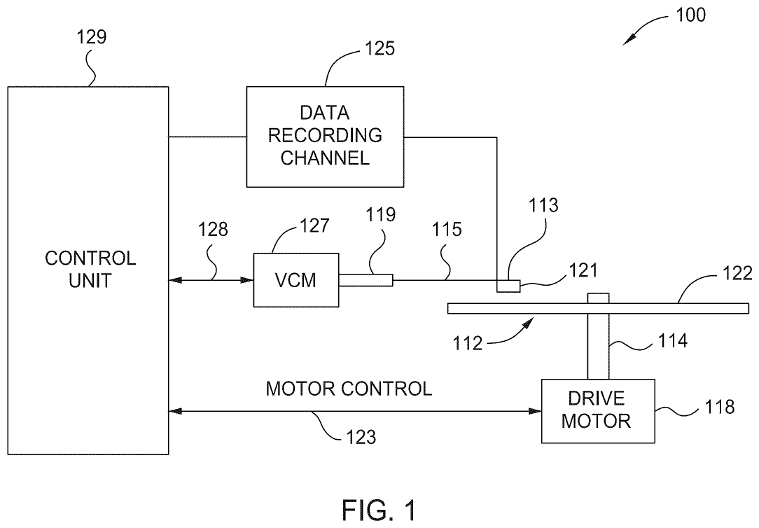

FIG. 1 is a schematic illustration of certain embodiments of a magnetic media drive 100 including a magnetic recording head with a SOT device. Such a magnetic media drive may be a single drive or comprise multiple drives. For illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

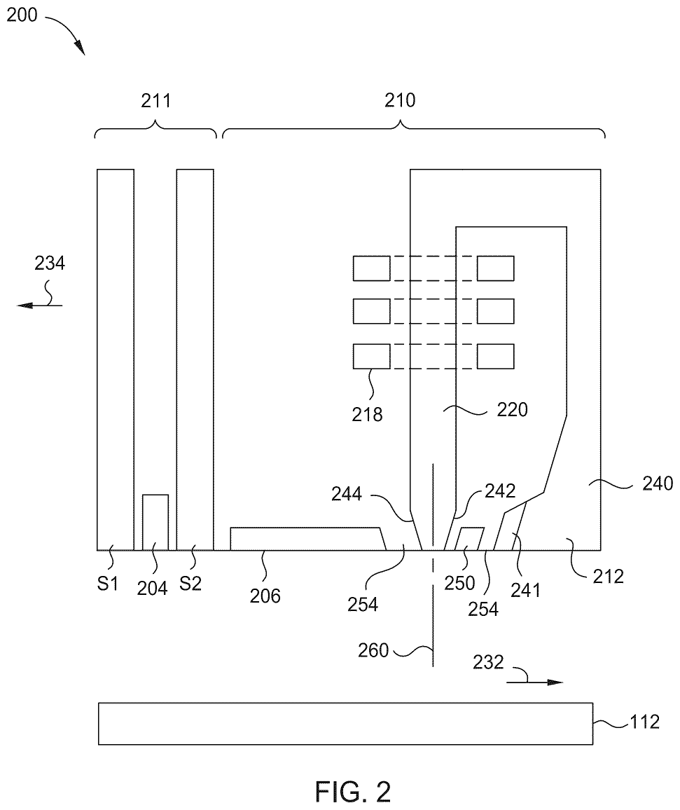

At least one slider 113 is positioned near the magnetic disk 112, and each slider 113 supports one or more magnetic head assemblies 121, including a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by a suspension 115. The suspension 115 provides a slight spring force which biases the slider 113 toward the disk surface 122. Each actuator arm 119 is attached to an actuator means 127. The actuator means 127, as shown in FIG. 2, may be a voice coil motor (VCM). The VCM includes a coil movable within a fixed magnetic field, the direction and speed of the coil movements being controlled by the motor current signals supplied by the control unit 129.

During operation of the disk drive 100, the rotation of the magnetic disk 112 generates an air bearing between the slider 113 and the disk surface 122 which exerts an upward force or lift on the slider 113. The air bearing thus counterbalances the slight spring force of suspension 115, and supports slider 113 off and slightly above the disk surface 122 by a small, substantially constant spacing during regular operation.

The various components of the disk drive 100 are operated by control signals generated by control unit 129, such as access control signals and internal clock signals. The control unit 129 typically comprises logic control circuits, storage means, and a microprocessor. The control unit 129 generates control signals to control various system operations such as drive motor control signals on line 123 and head position and seek control signals on line 128. The control signals on line 128 provide the desired current profiles to move optimally and position slider 113 to the desired data track on disk 112. Write and read signals are communicated to and from write and read heads on the assembly 121 by recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

It is to be understood that the embodiments discussed herein are applicable to a data storage device such as a hard disk drive (HDD) as well as a tape drive such as a tape embedded drive (TED) or an insertable tape media drive. An example TED is described in co-pending patent application titled “Tape Embedded Drive,” U.S. application Ser. No. 16/365,034, filed Mar. 31, 2019, assigned to the same assignee of this application, which is herein incorporated by reference. As such, any reference in the detailed description to an HDD or tape drive is merely for exemplification purposes and is not intended to limit the disclosure unless explicitly claimed. For example, references to disk media in an HDD embodiment are provided as examples only, and can be substituted with tape media in a tape drive embodiment. Furthermore, reference to or claims directed to magnetic recording devices or data storage devices are intended to include at least both HDD and tape drive unless HDD or tape drive devices are explicitly claimed.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232, and the read/write head 200 moves in the direction indicated by the arrow 234.

In some embodiments, the magnetic read head 211 is a magnetoresistive (MR) read head with an MR sensing element 204 located between MR shields S1 and S2. In other embodiments, the magnetic read head 211 is a magnetic tunnel junction (MTJ) read head that includes an MTJ sensing device 204 disposed between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of a SOT read head is described in a co-pending patent application titled “Topological Insulator Based Spin Torque Oscillator Reader,” U.S. application Ser. No. 17/828,226, filed May 31, 2022, assigned to the same assignee of this application, which is herein incorporated by reference. Another example of a SOT read head is described in co-pending patent applications titled “Non-Localized Spin Valve Reader Hybridized With Spin Orbit Torque Layer,” U.S. application Ser. No. 18/367,877, filed Sep. 13, 2023, and “Non-Localized Spin Valve Multi-Free-Layer Reader Hybridized With Spin Orbit Torque Layers,” U.S. application Ser. No. 18/367,882, filed Sep. 13, 2023, which is herein incorporated by reference.

The write head 210 includes a central or main pole 220, a leading shield 206, a trailing shield 240, an optional spin-orbital torque (SOT) device 250, and a coil 218 that excites the main pole 220. The coil 218 may have a “pancake” structure that winds around a back-contact between the main pole 220 and the trailing shield 240, instead of a “helical” structure shown in FIG. 2. For example, when included, e.g., to achieve a Microwave Assisted Magnetic Recording (MAMR) effect, the SOT device 250 is formed in a gap 254 between the main pole 220 and the trailing shield 240. In certain embodiments, the read/write head 200 additionally includes mechanisms (not shown) for supporting Heat Assisted Magnetic Recording (HAMR), which may include a waveguide coupled to a light source and a near field transducer (NFT) placed adjacent to the main pole 220 and coupled to the waveguide to convert the delivered light into a heating spot on the media.

The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may comprise magnetic materials, such as a NiFe alloy.

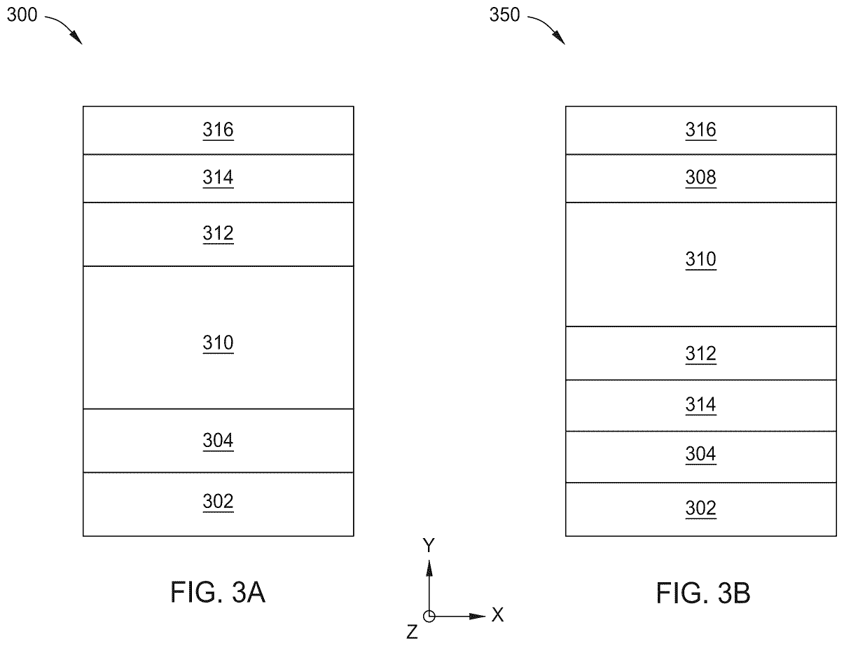

FIG. 3A is a schematic illustration of a forward spintronic material stack 300, according one embodiment. FIG. 3B is a schematic illustration of a reverse spintronic material stack 350, according another embodiment. Each spintronic stack 300, 350 may be utilized in the magnetic media drive 100 of FIG. 1, in the reader, and/or writer portions of the head 200 of FIG. 2, or other suitable magnetic media drives. Each spintronic stack 300, 350 may be utilized in a magnetic memory (such as MRAM) cell or logic cell. Aspects of the spintronic stacks 300, 350 may be used in combination with one another.

The spintronic stack 300 of FIG. 3A comprises an amorphous layer 302, a buffer layer 304 disposed over the amorphous layer 302, a topological semi-metal (TSM) layer 310 disposed over the buffer layer 304, an optional interlayer 312 disposed over the TSM layer 310, a ferromagnetic (FM) layer 314 disposed over the interlayer 312 or the TSM layer 310, and a cap layer 316 disposed on the FM layer 314. The TSM layer 310 may be referred to herein as a spin orbit torque (SOT) layer 310. While not shown, the amorphous layer 302 may be disposed on a seed layer. The buffer layer 304 may be a multilayer structure, as discussed further below. The buffer layer 304 and the interlayer 312 each individually comprises high resistivity materials.

The spintronic stack 350 of FIG. 3B is similar to the spintronic stack 300 of FIG. 3A; however, the layers of the spintronic stack 350 are ordered differently. The spintronic stack 350 comprises the amorphous layer 302, the buffer layer 304 disposed on the amorphous layer 302, the FM layer 314 disposed on the buffer layer 304, the optional interlayer 312 disposed on the FM layer 314, the TSM layer 310 disposed on the interlayer 312 or the FM layer 314, a barrier layer 308 disposed on the TSM layer 310, and the cap layer 316 disposed on the barrier layer 308.

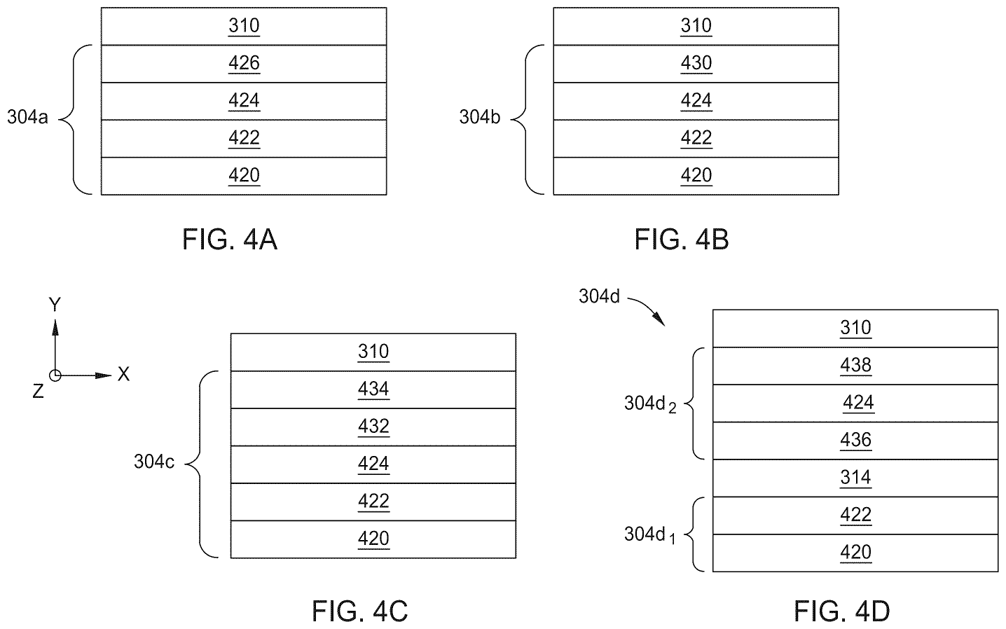

The buffer layer 304, the barrier layer 308, and the interlayer 312 help minimize shunting, act as migration barriers, and function as crystal symmetry transfer layers to promote or provide the (111) orientation to the TSM layer 310. The buffer layer 304 may be a multilayer structure, as discussed further below in FIGS. 4A-4C.

The amorphous layer 302 comprises a metal amorphous layer, such as CoFeTaN, NiTa NiW, NiFeTa, NiFeW, CoFeTa, or NiFeGe, or a bilayer amorphous metal oxide/metal amorphous layer, such as Al₂O₃/CoFeTaN, which may have a high resistance property, (“/” denotes separate sub-layers). In some embodiments, the amorphous layer 302 comprises CoFeTaN. The amorphous layer 302 has a thickness in y-direction of about 10 Å to about 50 Å. The TSM layer 310 comprises YPtBi having (111) orientation. In some embodiments, the TSM layer 310 comprises YPtBiX, where X is a dopant. The TM layer 310 has a thickness in the y-direction of about 50 Å to about 200 Å.

The barrier layer 308 comprises one or more materials selected from the group consisting of: X—AlGe, X—AlGeN (where Ge is about 0.5 at. % to about 50 at. % and N is less than about 20 at. %), HfN, TiN, NiFeGe, NiFeGeN, TaₓW₁₋ₓN, and TaₓHf₁₋ₓN (for nitrides of Ti, Hf, TaW, and TaHf, the N can be stoichiometric or nonstoichiometric). The material of the barrier layer 308 may be crystalline. In one embodiment, the barrier layer 308 comprises a first sublayer of HfN, and a second sublayer of TiN, or a first sublayer comprising MgO, and a second sublayer comprising NiGeAlN or IrAlGeN. The barrier layer 308 has a total thickness in the y-direction of about 3 Å to about 20 Å. When materials are written in the form of X-Q, the dash (-) indicates the material is an alloy.

The optional interlayer 312 comprises one or more materials selected from the group consisting of: stoichiometric or non-stoichiometric SiN, AlN, TiN, CrN, ZrN, MgO, MgTiO, MgAlO, TiO, TiN, HfN, X-QGe, X-QGeN, where Ge is about 0.5 at. % to about 50 at. % and nitrogen is less than about 20 at. %), where X is one of Co, Ni, Ru, Rh, or Ir, and Q is one of Al or Fe, and combinations thereof. The material of the interlayer 312 may be crystalline. The interlayer has a thickness in the y-direction of about 3 Å to about 20 Å. The FM layer 314 comprises CoB, CoFeB, CoFeBN, NiFe, CoFeNiN, CoFeN, CoFeHf, CoFeTa, CoFeTaN, orother suitable ferromagnetic materials or alloys. The cap layer 316 can be multiple layers and comprises a resistance material selected from the group consisting of: (1) IrₓHf_{y}Al_{z} or IrₓZr_{y}Al_{z}, where x is between about 40 at. % to about 90 at. %, y is about 0.5 at. % to about 60 at. %, and z is about 0.5 at. % to about 60 at. %; (2) ZrQX or HfQX, where X and Q are each individually selected from the group consisting of: Hf, Zr, Ru, Co, Cu, Ir, Pt, Al, Ti, Nb, Ni, RuAl, NiFe, and CoFe; (3) SiₓAl₁₋ₓN, TiₓAl₁₋ₓN, CrₓAl₁₋ₓN, and ZrₓAl₁₋ₓN, where x is a numeral between 0.005 and 1; and (4) nitrides of Si, Al, Ti, Cr, and Zr, or any alloy nitride composite combination thereof. The nitrogen content can be stoichiometric but is not required to be stoichiometric.

FIGS. 4A-4D illustrate various multilayer buffer layers 304a, 304b, 304c, 304d, according to various embodiments. Each buffer layer 304a-304c may individually be the buffer layer 304 of FIGS. 3A-3B. The layers of each buffer layer 304a-304d promote a (111) texture for the YPtBi layer 310. When materials are written in the form of “X-Q”, the dash (-) indicates the material is an alloy.

The buffer layer 304a of FIG. 4A comprises an amorphous oxide or nitride layer 420, an amorphous metal layer 422 disposed on the amorphous oxide or nitride layer, a textured pre-seed layer 424 disposed on the amorphous metal layer 422, and a (002) hexagonal or (111) fcc layer 426 disposed on the textured pre-seed layer 424. The TSM layer 310 comprising (111) YPtBi is disposed on the (002) hexagonal or (111) fcc layer 426.

The amorphous oxide or nitride layer 420 may comprise alumina and has a thickness in the y-direction of about 10 Å to about 40 Å. The amorphous metal layer 422 may comprise NiFeTa, CoFeTaN, NiFeTaN, or CoFeTa and has a thickness in the y-direction of about 10 Å to about 40 Å. The textured pre-seed layer 424 may comprise Ru or other (002) textured materials like Ti, Hf, and Zr, and has a thickness in the y-direction of about 4 Å to about 6 Å. The textured pre-seed layer 424 has a (002) orientation. The (002) hexagonal or (111) fcc layer 426 comprises a material selected from the group consisting of: Fe₂Mo, Fe₂W, Fe₂Ti, Fe₂(TaW), Co₂(NbAl), Co₂(TaAl), Co₂Ti, Co₂Ta, Co(Fe₂Ta), Co₂Nb, NiFeTa, Co₅Zr, Ni₅Zr, Ni₅Hf, (CuNi)₅Zr, AuScSn, BiCoZr, BiGdPt, BiDyPt, BiNiDy, and BiNiY. In some embodiments, the (002) hexagonal or (111) fcc layer 426 comprises a material selected from the group consisting of: Fe₂X, where X is one of Ti, Mo, Ta, or Ta_{z}W_{1-z}, (where z is a numeral between 0.005 and 1), Co₂X alloys, where X is one of Ti, Nb, Ta, TaAl, or NbAl, and (CoFe)₂Ta. A number of the Co₂X alloys exist both as hexagonal and fcc phases. The (111) fcc materials of the (002) hexagonal or (111) fcc layer 426 have a-axis lattice parameters in the range of about 6.6 Å to about 6.8 Å where (cF24—space group Fd-3m) materials are selected from the group consisting of: Co₂X, where X is one of Ti, Nb, Ta, Hf, or Zr, (cF24—space group F-43m materials), Ni₅Hf, and X₅Zr alloys, where X is one of Co, Ni, NiFe, or CuNi. There are also fcc (111) ternary alloys (cF12—space group F-43m) having a-axis lattice parameters in the range of about 6.4 Å to 6.7 Å that can used as buffer layers, such as AuScSn, BiCoZr, BiNiY, BiNiQ, or Bi—XQ alloys, where X is one of Ni, Pt, or Pd, and Q is a rare earth, such as Gd and Dy.

The (002) texture of the textured pre-seed layer 424 provides either a (002) or (111) texture to the (002) hexagonal or (111) fcc layer 426, allowing the (002) hexagonal or (111) fcc layer 426 to have a (002) or (111) orientation. The (002) or (111) orientation of the (002) hexagonal or (111) fcc layer 426 promotes the YPtiBi layer 310 to have a (111) orientation. The textured pre-seed layer 424 comprising Ru has an a_{hcp} value of about 2.71 Å, and the (002) hexagonal or (111) fcc layer 426 an a_{hcp} value of about 4.65 Å to about 4.85 Å. The YPtBi layer 310 has an a_{hcp} value of about 4.70 Å. Thus, the a_{hcp} values of the textured pre-seed layer 424 and the (002) hexagonal or (111) fcc layer 426 closely match that of the YPtBi layer 310, enabling the YPtBi layer 310 to have a (111) orientation.

The buffer layer 304b of FIG. 4B comprises the amorphous oxide or nitride layer 420, the amorphous metal layer 422 disposed on the amorphous oxide or nitride layer, the textured pre-seed layer 424 disposed on the amorphous metal layer 422, and a bcc or B2 (111) alloy layer 430 disposed on the textured pre-seed layer 424. The TSM layer 310 comprising (111) YPtBi is disposed on the bcc or B2 (111) alloy layer 430. The bcc or B2 (111) alloy layer has an a-axis lattice parameter of about 3.1 Å to about 3.4 Å. The bcc or B2 (111) alloy layer 430 comprises a material selected from the group consisting of: Zr, Hf, MgAu, Sc—X, where X is one of Al, Ni, Pd, or Au, Ti—X, where X is one of Ru, Rh, Pd, Pt, or Au, Ru—X, where X is one of Ti, Zr, Hf, or Ta, TaₓW₁₋ₓ (where x is a numeral between 0.005 and 1), (Ru—X and Ti—X need not be stoichiometric) Ir—X, where X is one of Sc, Ti, Y, or Zr, Hf—X, where X is one of Co, Ni, Ru, or Pt, Zr—X, where X is one of Ti, Co, Cu, Rh, Ru, or Os, and B2-alloy ternaries including (AlMo)_{0.5}Ti, (AlV)_{0.5}Ru, (AlZr)_{0.5}Ru, (HfTi)_{0.5}Ru, and Co (Fe, Ni, Nb)Zr, where examples include (Co4Ni)_{0.2}Zr, (Co4Fe)_{0.2}Zr, and (NbZr3)_{0.25}Co. The material of the bcc or B2 (111) alloy layer 430 may be ordered BCC or disordered BCC if the material is crystalline. The bcc or B2 (111) alloy layer 430 has a thickness in the y-direction of about 5 Å to about 40 Å.

The (111) orientation of the B2 alloy (111) layer 430 promotes the YPtiBi layer 310 to have a (111) orientation. The textured pre-seed layer 424 comprising Ru has an a_{hcp} value of about 2.71 Å, and the B2 alloy (111) layer 430 an a_{hcp} value of about 4.32 Å to about 4.75 Å. The YPtBi layer 310 has an a_{hcp} value of about 4.70 Å. Thus, the a_{hcp} values of the textured pre-seed layer 424 and the B2 alloy (111) layer 430 closely match that of the YPtBi layer 310, enabling the YPtBi layer 310 to have a (111) orientation.

The buffer layer 304c of FIG. 4C comprises the amorphous oxide or nitride layer 420, the amorphous metal layer 422 disposed on the amorphous oxide or nitride layer, the textured pre-seed layer 424 disposed on the amorphous metal layer 422, a first bcc or B2 layer 432 disposed on the textured pre-seed layer 424, and a second bcc or B2 layer 434 disposed on the first bcc or B2 layer 432. The TSM layer 310 comprising (111) YPtBi is disposed on the second bcc or B2 layer 434. The first and second bcc or B2 layers 432, 434 each has a (111) orientation. The (111) orientation of the first and second bcc or B2 layers 432, 434 promotes the YPtiBi layer 310 to have a (111) orientation. The first bcc or B2 layer 432 has a thickness in the y-direction of about 5 Å to about 40 Å, and the second bcc or B2 layer 434 has a thickness in they-direction of about 5 Å to about 40 Å.

The first bcc or B2 layer 432 comprises a material having an a_{hcp} value closer to that of the textured pre-seed layer 424, and the second bcc or B2 layer 434 comprises a material having an a_{hcp} value closer to that of the TSM layer 310. For example, the first bcc or B2 layer 432 has an a_{hcp} value between about 4.34 Å to about 4.54 Å, and the second bcc or B2 layer 434 has an a_{hcp} value between about 4.55 Å to about 4.75 Å. The first bcc or B2 layer 432 having slightly lower a-axis lattice parameter comprises a material selected from the group consisting of: RuTi, RhTi, (HfTi)_{0.5}Ru, (Co4Ni)_{0.2}Zr, and (Co4Fe)_{0.2}Zr. The second BCC or B2 layer 434 having slightly higher a-axis lattice parameter comprises a material selected from the group consisting of: Zr—X, where X is one of Ti, Co, Cu, Ru, Rh, or Os, Ir—X, where X is one of Sc, Y, or Zr, and TaₓW₁₋ₓ (where x is a numeral between 0.005 and 1). The first and second bcc or B2 alloy layers 432, 434 comprise different materials.

The buffer layer 304d of FIG. 4D comprises a first portion 304d₁ comprising the amorphous oxide or nitride layer 420, and the amorphous metal layer 422 disposed on the amorphous oxide or nitride layer, the FM layer 314 disposed on the first portion 304d₁, and a second portion 304d₂ disposed on the FM layer 314, the second portion 304d₂ comprising a polarization layer 436, the pre-seed layer 424 disposed on the polarization layer 436, and a bcc or B2 (111) layer 438 disposed on the pre-seed layer 424. The TSM layer 310 is disposed on the second portion 304d₂.

The polarization layer 436 is optional and may comprise MgO and has a thickness in the y-direction of about 3 Å to about 5 Å to effect the pre-seed layer 424 texture. The bcc or B2 (111) alloy layer 438 has an a-axis lattice parameter of about 3.1 Å to about 3.4 Å. The bcc or B2 (111) alloy layer 438 comprises a material selected from the group consisting of: MgAu, Sc—X, where X is one of Al, Ni, Pd, or Au, Ti—X, where X is one of Ru, Rh, Pd, Pt, or Au, Ru—X, where X is one of Ti, Zr, Hf, or Ta, TaₓW₁₋ₓ (where x is a numeral between 0.005 and 1), Ir—X, where X is one of Sc, Ti, Y, or Zr, Hf—X, where X is one of Co, Ni, Ru, or Pt, Zr—X, where X is one of Ti, Co, Cu, Rh, Ru, or Os, and B2-alloy ternaries including (AlMo)_{0.5}Ti, (AlV)_{0.5}Ru, (AlZr)_{0.5}Ru, (HfTi)_{0.5}Ru, (Co4Ni)_{0.2}Zr, (Co4Fe)_{0.2}Zr, and (NbZr3)_{0.25}Co. The material of the bcc or B2 (111) alloy layer 438 may be ordered BCC (B2) or disordered BCC (A2) if the material is crystalline. The bcc or B2 alloy layer 438 has a thickness in the y-direction of about 10 Å to about 15 Å. In such an embodiment, the FM layer 314 may comprise an amorphous material selected from the group consisting of: CoNbHf, CoB, CoFeB, CoFeBN, NiFeB, CoFeNiN, CoFeN, CoFeHfB, CoFeTaB, NiFeTaB, NiFeHfB, and other suitable amorphous ferromagnetic materials or alloys. Nitrogen can be added to all amorphous FM layers 314 in a low amount in certain embodiments.

Thus, each buffer layer 304a-304d promotes a (111) orientation in the TSM layer 310 while further functioning as a migration and shunt barriers for the spintronic stacks 300, 350. Further, the buffer layers 304a-304d have no negative chemical interactions with the TSM layer 310.

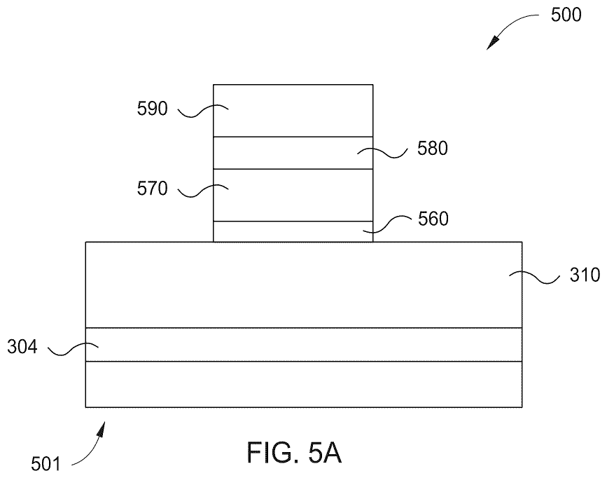

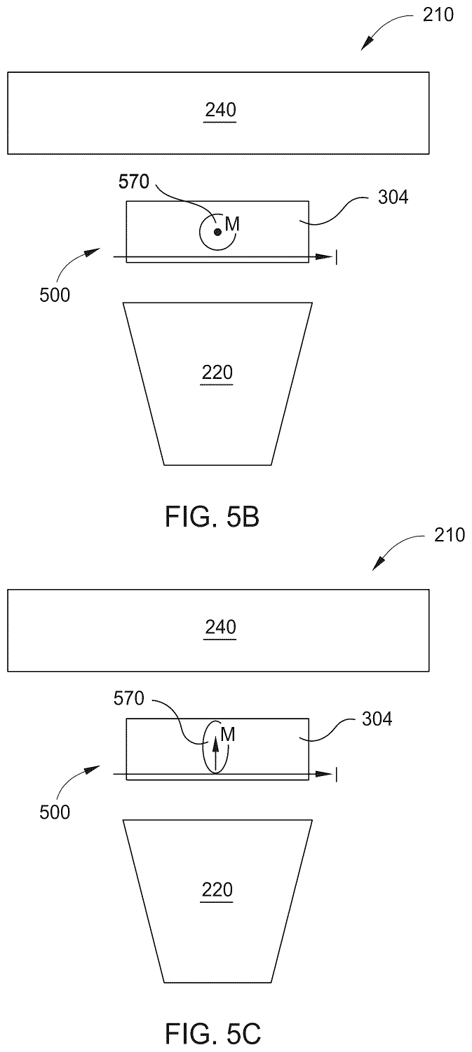

FIG. 5A is a schematic cross-sectional view of a SOT device 500 for use in a MAMR magnetic recording head, such as the MAMR magnetic recording head of the drive 100 of FIG. 1 or other suitable magnetic media drives. The SOT device 500 comprises a SOT layer 310 orientation formed over a buffer layer 304 formed over a substrate 501, such as the SOT layer 310 and the buffer layer 304 of FIG. 3A-3B. Thus, the SOT layer 310 may comprise YPtBi having a (111) orientation. A spin torque layer (STL) 570 is formed over the SOT layer 310. The STL 570 comprises a ferromagnetic material such as one or more layers of CoFe, CoIr, NiFe, and CoFeX alloy wherein X=B, Ta, Re, or Ir. The STL 570 may correspond to the FM layer 314 of the earlier figures.

In certain embodiments, an electrical current shunt block layer 560 is disposed between the SOT layer 310 and the STL 570. The electrical current shunt blocking layer 560 reduces electrical current from flowing from the SOT layer 310 to the STL 570 but allows spin orbital coupling of the SOT layer 310 and the STL 570. In certain embodiments, the electrical current shunt blocking layer 560 comprises a magnetic material that provides greater spin orbital coupling between the SOT layer 310 and the STL 570 than a nonmagnetic material. In certain embodiments, the electrical current shunt blocking layer 560 comprises a magnetic material of FeCo, FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni. Me is one or more of Si, Al, Hf, Zr, Nb, Ti, Ta, Mg, Y, or Cr. In certain embodiments, the electrical current shunt blocking layer 560 is formed to a thickness from about 10 Å to about 100 Å. In certain aspects, an electrical current shunt blocking layer 560 with a thickness of over 100 Å may reduce the spin-orbital coupling of the SOT layer 310 and the STL 570. In certain aspects, an electrical current shunt blocking layer having a thickness of less than 10 Å may not sufficiently reduce electrical current from SOT layer 310 to the STL 570.

In certain embodiments, additional layers are formed over the STL 570 such as a spacer layer 580 and a pinning layer 590. The pinning layer 590 can partially pin the STL 570. The pinning layer 590 comprises a single or multiple layers of PtMn, NiMn, IrMn, IrMnCr, CrMnPt, FeMn, other antiferromagnetic materials, or combinations thereof. The spacer layer 580 comprises single or multiple layers of magnesium oxide, aluminum oxide, other nonmagnetic materials, or combinations thereof.

FIGS. 5B-5C are schematic MFS views of certain embodiments of a portion of a MAMR magnetic recording head 210 with a SOT device 500 of FIG. 5A. The MAMR magnetic recording head 210 can be the magnetic recording head FIG. 2 or other suitable magnetic recording heads in the drive 100 of FIG. 1 or other suitable magnetic media drives such as tape drives. The MAMR magnetic recording head 210 includes a main pole 220 and a trailing shield 240 in a track direction. The SOT device 500 is disposed in a gap between the main pole and the trailing shield 240.

During operation, charge current through a SOT layer 310 acting as a spin Hall layer generates a spin current in the YPtBi layer. The spin orbital coupling of the YPtBi layer and a spin torque layer (STL) 570 causes switching or precession of magnetization of the STL 570 by the spin orbital coupling of the spin current from the SOT layer 310. Switching or precession of the magnetization of the STL 570 can generate an assisting AC field to the write field. Energy-assisted magnetic recording heads based on SOT have multiple times greater power efficiency than MAMR magnetic recording heads based on spin transfer torque. As shown in FIG. 5B, an easy axis of a magnetization direction of the STL 570 is perpendicular to the MFS from shape anisotropy of the STL 570, from the pinning layer 590 of FIG. 5A, and/or from hard bias elements proximate to the STL 570. As shown in FIG. 5C, an easy axis of a magnetization direction of the STL 570 is parallel to the MFS from shape anisotropy of the STL 570, from the pinning layer 590 of FIG. 5A, and/or from complex bias elements proximate to the STL 570.

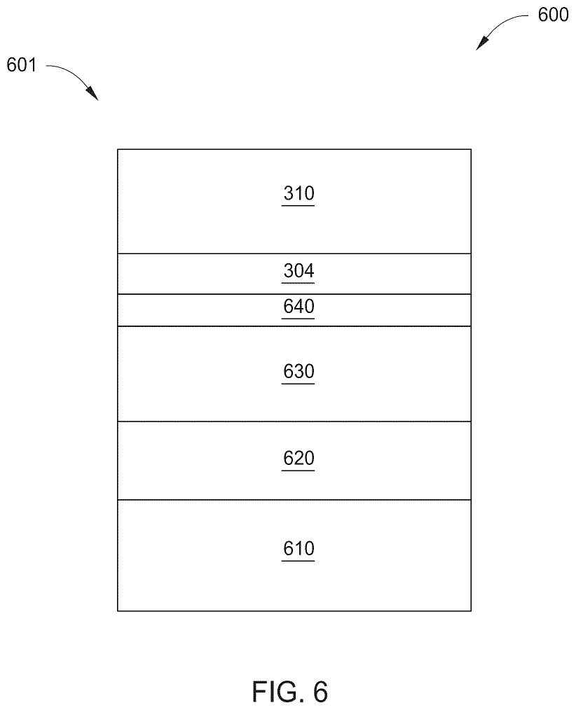

FIG. 6 is a schematic cross-sectional view of an SOT MTJ 601 used as a MRAM device 600. The MRAM device 600 comprises a reference layer (RL) 610, a spacer layer 620 over the RL 610, a recording layer 630 over the spacer layer 620, a buffer layer 304 over an electrical current shunt block layer 640 over the recording layer 630, and a SOT layer 310 over the buffer layer 304. The SOT layer 310 and the buffer layer 304 may be the SOT layer 310 and the buffer layer 304 of FIGS. 3A-3B. The RL 610 may be the FM layer 314 of those figures. Thus, the SOT layer 310 may comprise YPtBi having a (111) orientation.

The RL 610 comprises single or multiple layers of CoFe, other ferromagnetic materials, and combinations thereof. The spacer layer 620 comprises single or multiple layers of magnesium oxide, aluminum oxide, other dielectric materials, or combinations thereof. The recording layer 630 comprises single or multiple layers of CoFe, NiFe, other ferromagnetic materials, or combinations thereof.

As noted above, in certain embodiments, the electrical current shunt block layer 640 is disposed between the buffer layer 304 and the recording layer 630. The electrical current shunt blocking layer 640 reduces electrical current from flowing from the SOT layer 310 to the recording layer 630. The electrical current shunt blocking layer 640 still allows spin orbital coupling of the SOT layer 310 and the recording layer 630. For example, writing to the MRAM device can be enabled by the spin orbital coupling of the TSM layer and the recording layer 630, which allows switching of magnetization of the recording layer 630 by the spin orbital coupling of the spin current from the SOT layer 310. In certain embodiments, the electrical current shunt blocking layer 640 comprises a magnetic material that provides greater spin orbital coupling between the SOT layer 310 and the recording layer 630 than a nonmagnetic material. In certain embodiments, the electrical current shunt blocking layer 640 comprises a magnetic material of FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof, in which M is one or more of B, Si, P, Al, Hf, Zr, Nb, Ti, Ta, Mo, Mg, Y, Cu, Cr, and Ni; and Me is Si, Al, Hf, Zr, Nb, Ti, Ta, Mg, Y, or Cr.

The MRAM device 600 of FIG. 6 may include other layers, such as pinning layers, pinning structures (e.g., a synthetic antiferromagnetic (SAF) pinned structure), electrodes, gates, and other structures. Other MRAM devices besides the structure of FIG. 6 can be formed utilizing a SOT layer 310 over a buffer layer 304 to form a SOT MTJ 601. For example, additional SOT-based MRAM devices utilizing the various materials and structures disclosed here can be made in accordance with the embodiments described in co-pending application “Buffer Layers to Grow BiSb and YPtBi to Match the Crystal Symmetry of Interlayers and Ferromagnetic layers to Generate Spin-Polarized Current,” U.S. patent application Ser. No. 19/041,211, filed Jan. 30, 2025, the disclosures of which are hereby incorporated by reference.

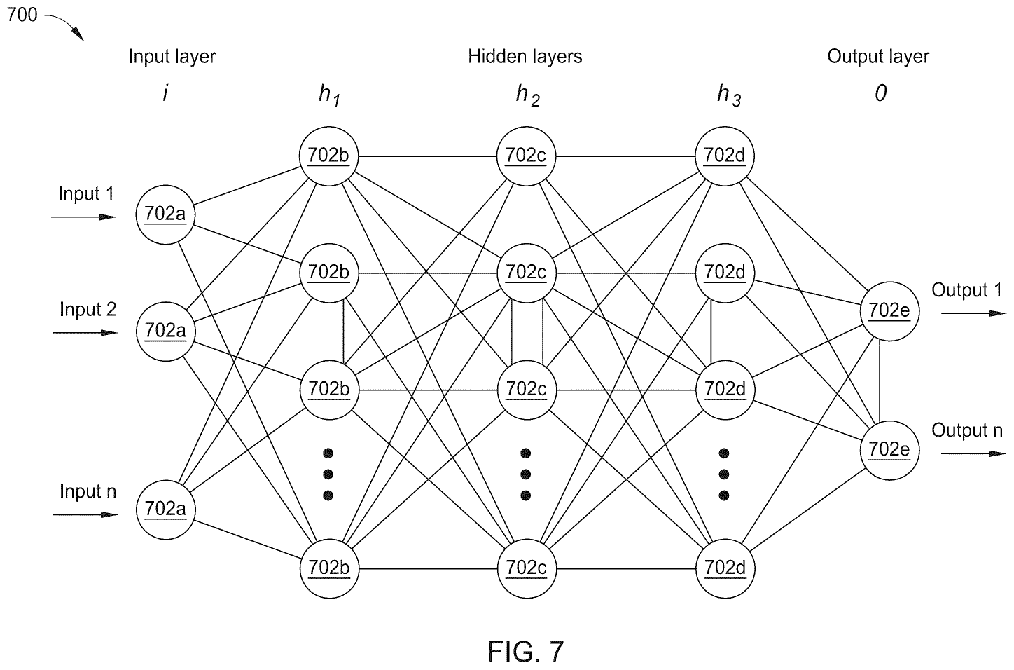

FIG. 7 illustrates a schematic of a simplified deep neural network (DNN) or logic cell 700, according to one embodiment. The DNN 700 comprises a plurality of cells or neural nodes 702a, 702b, 702c, 702d, 702e (collectively referred to herein as neural nodes 702). Each neural node 702 comprises a plurality of spin orbital-spin orbital (SO-SO) cells, where each SO-SO cell is a three-terminal device, comprising a control or weight, an input, and an output. Each SO-SO cell may comprise one or more of the spintronic stacks 300a-300d of FIGS. 3A-3B. An input current (input 1, input 2, input n) is applied to a first input layer (i) of neural nodes 702a and multiplied by the control or weight.

The output of each neural node 702a of the input layer is then output to each neural node 702b in a first hidden layer (h1) of the DNN 700 as the input for each neural node 702b, where each received input at each neural node 702b is then multiplied by a respective weight for the respective input of each neural node 702b. A weight may conceptually represent a strength of the connection between a neural node in one layer (e.g., neural node 702a) and another neural node in the next layer (e.g., neural node 702b). The results of the multiplications are collectively summed together and sent to a non-linear activation function (not shown here), such as a step or a rectified linear unit (ReLU) function, which determines the final output for that neural node 702b. This multiplication, summation and activation function sequence of processes is then repeated in the various layers h2, h3, etc. throughout the DNN. While three hidden layers are shown, the DNN 700 may comprise any number of hidden layers. Finally, the output of the last hidden layer (here, the third hidden layer) is output to output neural nodes 702e of an output layer (o) as a final result.

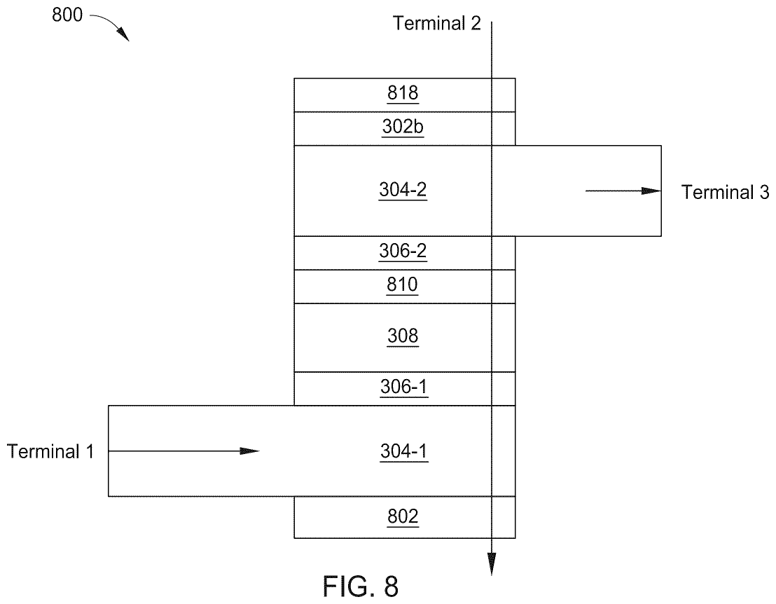

FIG. 8 illustrates a spin orbital-spin orbital (SO-SO) device 800, according to one embodiment. The SO-SO device 800 may be utilized within the DNN 700 of FIG. 7, such as a SO-SO cell. The various layers of the SO-SO device 800 are not drawn to scale, and are intended for illustrative purposes only. The SO-SO devices may be referred to herein as SOT devices. A plurality of SO-SO devices 800 may be configured to function as a neural node 102 of FIG. 7. Thus, a collection of SO-SO devices may be configured to represent a layer (i, h1, h2, h3, o) of the DNN of FIG. 7.

In some embodiments, the SO-SO device 800 comprises a seed layer 802, a first spin orbit torque (SOT) layer 310-1 (SOT1) disposed on the seed layer 802, a first interlayer 312-1 disposed on the first SOT layer 310-1, a ferromagnetic (FM) layer 314 disposed on the first interlayer 312-1, an oxide layer 810 (e.g., an MgO layer) disposed on the FM layer 314, a second interlayer 312-2 disposed on the oxide layer 810, a second SOT layer 310-2 (SOT2) disposed on the second interlayer 312-2, a buffer layer 304 disposed on the second SOT layer 310-2, and a cap layer 818 disposed on the buffer layer 304. The oxide layer 810 may comprise other materials, such as oxides of Ti, V, Cr, Mn, Fe, Ni, Zr, nitrides of Sc, Ti, V, Cr, Fe, Zr, Mo, Ta, Hf, W, carbides of Sc, Ti, V, Zr, Ta, Hf, W, and alloy combinations thereof.

The first and second interlayers 312-1, 312-2 may each individually be the interlayer 312 of FIGS. 3-4. The buffer layer 304 may be the buffer layer 304 of FIGS. 3-4. The SOT1 310-1 and the SOT2 310-2 may each individually be the SOT layer 310 of FIGS. 3-4. The FM layer 314 may be the FM layer 314 of FIGS. 3-4.

In some embodiments, the SO-SO device 800 comprises three terminals or interconnects. The first SOT layer 310-1 is coupled to an interconnect or terminal 1. The second SOT layer 310-2 is coupled to an interconnect or terminal 3, where the interconnect or terminal 3 is coupled to the first SOT layer 310-1 of a second SO-SO device via terminal 1. An input current is applied to terminal 2 (representing an input Xₙ current to a neural node) and it flows out-of-plan (current-perpendicular-to-plane (CPP)) through the whole stack toward the seed layer 802. The arrows associated with the terminals indicate the direction of current flows, according to some embodiments. The interconnects or terminals serves as connection points for joining two or more SO-SO devices. Thus, multiple SO-SO devices 800 can be arranged to build out various circuits.

Therefore, by utilizing a buffer layer having a hexagonal (002)or fcc (111) orientation in a spintronic stack, the TSM layer is able to grow in a (111) orientation. Furthermore, such buffer layers comprising the above-mentioned materials function as migration and shunt barriers for the spintronic stacks, and have no negative chemical interactions with the TSM layer.

In one embodiment, a spintronic stack comprises a YPtBi layer having a (111) orientation, a ferromagnetic layer, and a buffer layer, the buffer layer comprising: an amorphous oxide or nitride layer, an amorphous metal layer disposed on the amorphous oxide or nitride layer, a textured pre-seed layer disposed on the amorphous metal layer, and a (002)hexagonal or (111) fcc layer disposed on the textured pre-seed layer, the (002)hexagonal or (111) fcc layer having a-axis lattice parameters around 4.6 Å to 4.8 Å when the (002)hexagonal or (111) fcc layer has a (002)hexagonal orientation, the (002)hexagonal or (111) fcc layer having a (002)hexagonal orientation comprising an alloy material selected from the group consisting of: Fe₂X, where X is one of Ti, Mo, Ta, or Ta_{z}W_{1-z}, (where z is a numeral between 0.005 and 1), Co₂X alloys, where X is one of Ti, Nb, Ta, TaAl, or NbAl, and (CoFe)₂Ta. The (111) fcc materials of the (002) hexagonal or (111) fcc layer have a-axis lattice parameters in the range of about 6.6 Å to about 6.8 Å where (cF24—space group Fd-3m) materials are selected from the group consisting of: Co₂X, where X is one of Ti, Nb, Ta, Hf, or Zr, (cF24—space group F-43m materials), Ni₅Hf, and X₅Zr alloys, where X is one of Co, Ni, NiFe, or CuNi. There are also fcc (111) ternary alloys (cF12—space group F-43m) having a-axis lattice parameters in the range of about 6.4 Å to 6.7 Å that can used as buffer layers, such as AuScSn, BiCoZr, BiNiY, or Bi—XQ alloys, where X is one of Ni, Pt, or Pd, and Q is a rare earth, such as Gd and Dy.

The textured pre-seed layer comprises Ru, wherein the amorphous oxide or nitride layer comprises alumina, and wherein the amorphous metal layer comprises NiFeTa or CoFeTaN. The YPtBi layer is disposed between the buffer layer and the ferromagnetic layer. The ferromagnetic layer is disposed between the buffer layer and the YPtBi layer. The (002)hexagonal or (111) fcc layer has a thickness of about 5 Å to about 40 Å. A memory cell comprises the spintronic stack. A logic cell comprises the spintronic stack. A magnetic sensor comprises the spintronic stack.

In another embodiment, a spintronic stack comprises a YPtBi layer having a (111) orientation, a ferromagnetic layer, and a buffer layer, the buffer layer comprising: an amorphous oxide or nitride layer, an amorphous metal layer disposed on the amorphous oxide or nitride layer, a textured pre-seed layer disposed on the amorphous metal layer, and a bcc or B2 alloy layer disposed on the textured pre-seed layer, the bcc or B2 alloy layer having an a-axis lattice parameter of about 3.1 Å to about 3.4 Å, the bcc or B2 alloy layer comprising a material selected from the group consisting of: MgAu, Sc—X, where X is one of Al, Ni, Pd, or Au, Ti—X, where X is one of Ru, Rh, Pd, Pt, or Au, Ru—X where X is one of Ti, Zr, Hf, or Ta, TaₓW₁₋ₓ (where x is a numeral between 0.005 and 1), Ir—X, where X is one of Sc, Ti, Y, or Zr, Hf—X, where X is one of Co, Ni, Ru, Pt, Zr—X, where X is one of Ti, Co, Cu, Rh, Ru, and Os, and B2-alloy ternaries including (AlMo)_{0.5}Ti, (AlV)_{0.5}Ru, (AlZr)_{0.5}Ru, (HfTi)_{0.5}Ru, (Co4Ni)_{0.2}Zr, (Co4Fe)_{0.2}Zr, and (NbZr3)_{0.25}Co.

The B2 alloy layer has a (111) orientation. The textured pre-seed layer comprises Ru having a (002)orientation. The YPtBi layer is disposed between the buffer layer and the ferromagnetic layer. The ferromagnetic layer is disposed between the buffer layer and the YPtBi layer. A memory cell comprises the spintronic stack. A logic cell comprises the spintronic stack. A magnetic sensor comprises the spintronic stack.

In yet another embodiment, a spintronic stack comprises a YPtBi layer having a (111) orientation, a ferromagnetic layer, and a buffer layer, the buffer layer comprising: an amorphous oxide or nitride layer, an amorphous metal layer disposed on the amorphous oxide or nitride layer, a textured pre-seed layer disposed on the amorphous metal layer, a first bcc or B2 alloy layer disposed on the textured pre-seed layer, the first bcc or B2 alloy layer comprising a material selected from the group consisting of: RuTi, RhTi, (HfTi)_{0.5}Ru, (Co4Ni)_{0.2}Zr, and (Co4Fe)_{0.2}Zr, and a second bcc or B2 alloy layer disposed on the first bcc or B2 alloy layer, the second bcc or B2 alloy layer comprising a material selected from the group consisting of: Zr—X, where X is one of Ti, Co, Cu, Ru, Rh, or Os, Ir—X, where X is one of Sc, Y, or Zr, and TaₓW₁₋ₓ (where x is a numeral between 0.005 and 1).

The first bcc layer has a lower a_{hcp} value than the second bcc layer. The first bcc layer has a thickness of about 5 Å to about 40 Å, and wherein the second bcc layer has a thickness of about 5 Å to about 40 Å. A memory cell comprises the spintronic stack. A logic cell comprises the spintronic stack. A magnetic sensor comprises the spintronic stack.

While the foregoing is directed to embodiments of the present disclosure, other and further embodiments of the disclosure may be devised without departing from the basic scope thereof, and the scope thereof is determined by the claims that follow.

What is claimed is:

1. A spintronic stack, comprising:
a YPtBi layer having a (111) orientation;
a ferromagnetic layer; and
a buffer layer, the buffer layer comprising:
an amorphous oxide or nitride layer;
an amorphous metal layer disposed on the amorphous oxide or nitride layer;
a textured pre-seed layer disposed on the amorphous metal layer; and
a (002) hexagonal or (111) fcc layer disposed on the pre-seed layer, the (002)hexagonal or (111) fcc layer comprising a material selected from the group consisting of:
Fe₂X, where X is one of Ti, Mo, Ta, or Ta_{z}W_{1-z}, where z is a numeral between 0.005 and 1,
Co₂X alloys, where X is one of Ti, Nb, Ta, TaAl, or NbAl,
(CoFe)₂Ta,
Co₂X, where X is one of Ti, Nb, Ta, Hf, or Zr,
Ni₅Hf, and
X₅Zr alloys, where X is one of Co, Ni, NiFe, or CuNi,
AuScSn,
BiCoZr,
BiNiY, and
Bi—XQ alloys, where X is one of Ni, Pd, or Pt, and Q is Gd or Dy.

2. The spintronic stack of claim 1, wherein the textured pre-seed layer comprises Ru, wherein the amorphous oxide or nitride layer comprises alumina, and wherein the amorphous metal layer comprises NiFeTa, CoFeTaN, NiFeTaN, or CoFeTa.

3. The spintronic stack of claim 1, wherein the YPtBi layer is disposed between the buffer layer and the ferromagnetic layer.

4. The spintronic stack of claim 1, wherein the ferromagnetic layer is disposed between the buffer layer and the YPtBi layer.

5. The spintronic stack of claim 1, wherein the (002) hexagonal or (111) fcc layer has a thickness of about 5 Å to about 40 Å.

6. A memory cell comprising the spintronic stack of claim 1.

7. A logic cell comprising the spintronic stack of claim 1.

8. A magnetic sensor comprising the spintronic stack of claim 1.

9. A magnetic recording device comprising the spintronic stack of claim 1.

10. A spintronic stack, comprising:
a YPtBi layer having a (111) orientation;
a ferromagnetic layer; and
a buffer layer, the buffer layer comprising:
an amorphous oxide or nitride layer;
an amorphous metal layer disposed on the amorphous oxide or nitride layer;
a textured pre-seed layer disposed on the amorphous metal layer; and
a bcc or B2 alloy layer disposed on the textured pre-seed layer, the bcc or B2 alloy layer comprising a material selected from the group consisting of:
MgAu,
Sc—X, where X is one of Al, Ni, Pd, or Au,
Ti—X, where X is one of Ru, Rh, Pd, Pt, or Au,
Ru—X where X is one of Ti, Zr, Hf, or Ta,
TaₓW₁₋ₓ (where x is a numeral between 0.005 and 1),
Ir—X, where X is one of Sc, Ti, Y, or Zr,
Hf—X, where X is one of Co, Ni, Ru, or Pt,
Zr—X, where X is one of Ti, Co, Cu, Rh, Ru, or Os,
(AlMo)_{0.5}Ti,
(AlV)_{0.5}Ru,
(AlZr)_{0.5}Ru,
(HfTi)_{0.5}Ru,
(Co4Ni)_{0.2}Zr,
(Co4Fe)_{0.2}Zr, and
(NbZr3)_{0.25}Co.

11. The spintronic stack of claim 10, wherein the bcc or B2 alloy layer has a (111) orientation.

12. The spintronic stack of claim 10, wherein the textured pre-seed layer comprises Ru having a (002)orientation.

13. The spintronic stack of claim 10, wherein the YPtBi layer is disposed between the buffer layer and the ferromagnetic layer.

14. The spintronic stack of claim 10, wherein the ferromagnetic layer is disposed between the buffer layer and the YPtBi layer.

15. A memory cell comprising the spintronic stack of claim 10.

16. A logic cell comprising the spintronic stack of claim 10.

17. A magnetic sensor comprising the spintronic stack of claim 10.

18. A magnetic recording device comprising the spintronic stack of claim 10.

19. A spintronic stack, comprising:
a YPtBi layer having a (111) orientation;
a ferromagnetic layer; and
a buffer layer, the buffer layer comprising:
an amorphous oxide or nitride layer;
an amorphous metal layer disposed on the amorphous oxide or nitride layer;
a textured pre-seed layer disposed on the amorphous metal layer;
a first bcc or B2 alloy layer disposed on the textured pre-seed layer; and
a second bcc or B2 alloy layer disposed on the first bcc or B2 alloy layer,
the first and second bcc or B2 alloy layers each individually comprising a material selected from the group consisting of:
MgAu,
Sc—X, where X is one of Al, Ni, Pd, or Au,
Ti—X, where X is one of Ru, Rh, Pd, Pt, or Au,
Ru—X where X is one of Ti, Zr, Hf, or Ta,
TaₓW₁₋ₓ (where x is a numeral between 0.005 and 1),
Ir—X, where X is one of Sc, Ti, Y, or Zr,
Hf—X, where X is one of Co, Ni, Ru, or Pt,
Zr—X, where X is one of Ti, Co, Cu, Rh, Ru, or Os,
(AlMo)_{0.5}Ti,
(AlV)_{0.5}Ru,
(AlZr)_{0.5}Ru,
(HfTi)_{0.5}Ru,
(Co4Ni)_{0.2}Zr,
(Co4Fe)_{0.2}Zr, and
(NbZr3)_{0.25}Co,
wherein the first and second bcc or B2 alloy layers comprise different materials.

20. The spintronic stack of claim 19, wherein the first bcc or B2 alloy layer has a lower a_{hcp} value than the second bcc layer.

21. The spintronic stack of claim 19, wherein the first bcc or B2 alloy layer has a thickness of about 5 Å to about 40 Å, and wherein the second bcc or B2 alloy layer has a thickness of about 5 Å to about 40 Å.

22. A memory cell comprising the spintronic stack of claim 19.

23. A logic cell comprising the spintronic stack of claim 19.

24. A magnetic sensor comprising the spintronic stack of claim 19.

25. A magnetic recording device comprising the spintronic stack of claim 19.
